(19) United States
(12) Patent Application Publication
(10) Pub. No.: US 2022/0208661 A1
(43) Pub. Date: Jun. 30, 2022

(54) QFN/QFP PACKAGE WITH INSULATED TOP-SIDE THERMAL PAD

(71) Applicant: Texas Instruments Incorporated, Dallas, TX (US)

(72) Inventors: Wenli Zhang, Allen, TX (US); Paul Leroy Brohlin, Parker, TX (US)

(73) Assignee: Texas Instruments Incorporated, Dallas, TX (US)

(21) Appl. No.: 17/138,983

(22) Filed: Dec. 31, 2020

(51) Int. Cl. H01L 23/495; H01L 23/31; H01L 21/56

(52) U.S. Cl. CPC H01L 23/49568; H01L 24/29; H01L 21/56; H01L 23/3121

(57) ABSTRACT

A packaged electronic device comprises a die attach pad enclosed by a package structure, a semiconductor die mounted to a side of the die attach pad, a conductive plate and a polymer layer having a first side on a side of the conductive plate and a second side on the die attach pad. A method of manufacturing a packaged electronic device comprises attaching a first side of a polymer layer to a first side of a conductive plate, attaching a first side of a die attach pad to a second side of the polymer layer and attaching a first side of a semiconductor die to a second side of the die attach pad.

### BACKGROUND

Thermal pad can be used to dissipate thermal energy from the top side of a semiconductor package, such as a quad flat pack (QFP) or quad flat no-lead (QFN) package. However, QFN and QFP packages with top-side thermal pad have limited heat dissipation capability due to limited exposed pad area and thin lead frame as die attach pad. In particular, the heat dissipation capability of these devices are often insufficient for a high-voltage power device used in high power applications, such as DC to DC converters or other switching power supplies. Also, non-insulated thermal pad can violate voltage spacing requirements in some applications. An additional heat slug can be attached on an exposed thermal pad of a previously molded QFN or QFP package using solder, conductive silver epoxy/paste, or non-conductive epoxy. However, no insulation function is provided when solder or conductive silver epoxy or paste is used for slug attachment. Non-conductive epoxy typically has low thermal conductivity (e.g., 0.5-2 W per meter per degree K) that limits thermal performance, and long-term mechanical and electrical reliability of non-conductive epoxy is a concern. Another approach uses a metallized ceramic substrate as a chip carrier with a copper lead frame, leads and chips attached to the substrate, but this assembly process is complex and material cost is high.

### SUMMARY

In one aspect, a packaged electronic device includes a die attach pad, a semiconductor die, a conductive plate and a polymer layer. The die attach pad has a first side and an opposite second side, and the semiconductor die has a first side mounted to the second side of the die attach pad. The polymer layer has a first side on a first side of the conductive plate, and a second side on the first side of the die attach pad. A package structure encloses the semiconductor die and the die attach pad and exposes a portion of the second side of the conductive plate.

In another aspect, a packaged electronic device includes a die attach pad and a semiconductor die, the semiconductor die mounted to a side of the die attach pad. A conductive plate, and a polymer layer has a first side on a side of the conductive plate, is attached on a second side of the exposed die attach pad.

In a further aspect, a method of manufacturing a packaged electronic device includes attaching a first side of a polymer layer to a first side of a conductive plate, attaching a first side of a die attach pad to a second side of the polymer layer, attaching a first side of a semiconductor die to a second side of the die attach pad, coupling a conductive feature of the semiconductor die to a lead frame, and forming a package structure that encloses the semiconductor die and the die attach pad and exposes a portion of a second side of the conductive plate.

### BRIEF DESCRIPTION OF THE DRAWINGS

FIG. 1 is a sectional side elevation view of a packaged electronic device with a polymer layer bonded between a conductive plate and a die attach pad.

FIG. 2 is a process flow diagram of a method of manufacturing a packaged electronic device.

FIG. 3 is a sectional side elevation view of the packaged electronic device of FIG. 1 undergoing a deposition process to deposit a polymer layer on a conductive plate.

FIG. 4 is a sectional side elevation view of the packaged electronic device of FIG. 1 undergoing a placement operation to position the conductive plate on an adhesive carrier tape.

FIG. 5 is a sectional side elevation view of the packaged electronic device of FIG. 1 undergoing a placement operation to place a lead frame with a die attach pad on the polymer layer.

FIG. 6 is a sectional side elevation view of the packaged electronic device of FIG. 1 undergoing a heated pressure bonding process to bond the polymer layer to the die attach pad.

FIG. 7 is a sectional side elevation view of the packaged electronic device of FIG. 1 undergoing a die attachment process to attach a semiconductor die to the die attach pad.

FIG. 8 is a sectional side elevation view of the packaged electronic device of FIG. 1 undergoing a wire bonding process to electrically couple conductive features of the semiconductor die to pins of the lead frame.

FIG. 8A is a perspective view of the packaged electronic device of FIG. 1 following the wire bonding process of FIG. 8.

FIG. 9 is a sectional side elevation view of the packaged electronic device of FIG. 1 undergoing a molding process to create a package structure.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating.

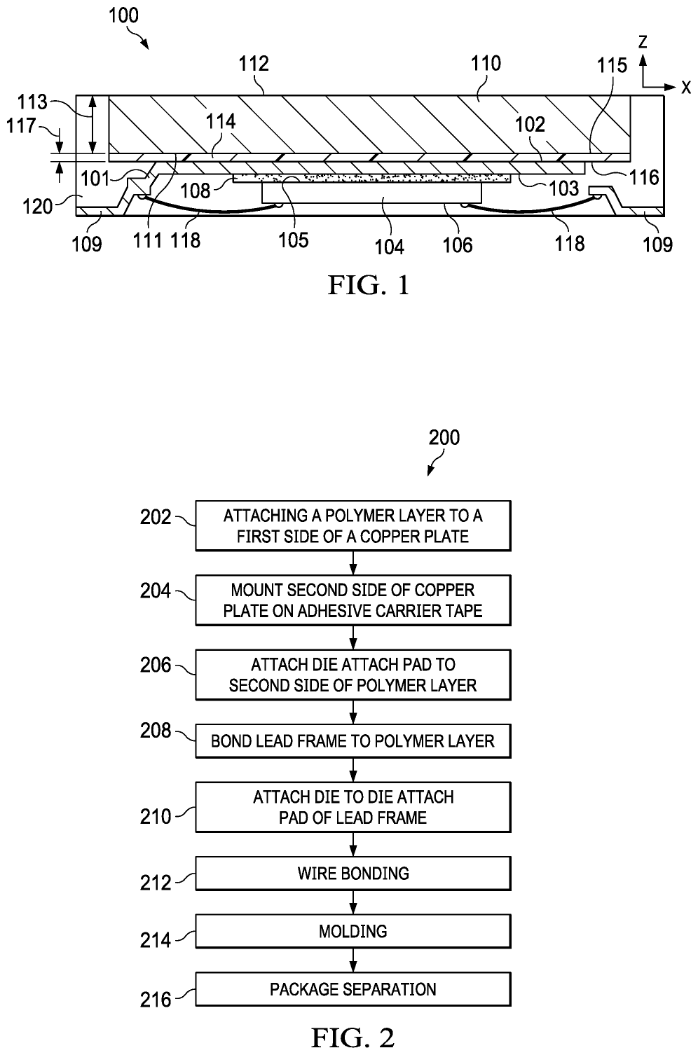

FIG. 1 shows a packaged electronic device 100 with an insulated top-side conductive plate thermal pad in a QFN package for heat dissipation out of the upper side of the package. The packaged electronic device 100 includes a die attach pad 101 formed from a starting lead frame. In one example, the die attach pad 101 is or includes copper, such as copper or a copper alloy. In other examples, the die attach pad 101 is or includes aluminum or another electrically conductive material. The die attach pad 101 has a first side 102 (e.g., top side in the view of FIG. 1) and an opposite second side 103 (e.g., the bottom side). The packaged electronic device 100 also includes a semiconductor die 104 with a top or first side 105 mounted to the second side 103 of the die attach pad 101, and a bottom or second side 106. In the illustrated example, the die 104 is mounted to the second side 103 of the die attach pad 101 by a solder or epoxy layer 108. The packaged electronic device 100 includes conductive leads 109 also formed from a starting lead frame positioned around four sides of the QFN or QFP structure, with bottoms and side portions exposed for solder connection to a host printed circuit board (PCB, not shown). In one example, the leads 109 are or include copper, such as copper or a copper alloy. In other examples, the leads 109 are or include aluminum or another electrically conductive material.

The packaged electronic device 100 also includes a conductive plate 110. In one example, the conductive plate 110 is or includes copper. In other examples, the conductive plate 110 is or includes aluminum or another electrically conductive material. The conductive plate 110 has a first side 111 and an opposite second side 112. In one example, the first side 111 and the second side 112 of the conductive plate 110 are spaced apart from one another by a plate thickness 113 of 0.25 mm or more and 3.0 mm or less. In one implementation, the plate thickness 113 is 0.50 mm or more and 1.0 mm or less.

The conductive plate 110 is electrically insulated from the die attach pad 101 by the polymer layer 114. The heat generated by semiconductor die 104 is dissipated from the second side 112 of the conductive plate 110 through the die attach pad 101 and the polymer layer 114 bonded between the conductive plate 110 and the die attach pad 101. The polymer layer 114 in one example is or includes a polymer-based epoxy with high thermal conductivity and high dielectric strength. The polymer layer 114 has an upper first side 115 and an opposite (e.g., lower) second side 116. The first side 115 of the polymer layer 114 is engaged on and bonded to the first side 111 of the conductive plate 110. The second side 116 of the polymer layer 114 is engaged on and bonded to the first side 102 of the die attach pad 101. The polymer layer 114 is an electrically insulative material. In one example, the polymer layer 114 has a dielectric strength of 10 kV/mm or more, such as 10 kV/mm to 50 kV/mm. In this or another example, the polymer layer 114 has a thermal conductivity of 5 W per meter per degree K or more, such as 5-20 W per meter per degree K. In these or another example, the first side 115 and the second side 116 of the polymer layer 114 are spaced apart from one another by a thickness 117 of 100 μm or more, such as 100-500 μm. In these or another example, the polymer layer 114 has a breakdown voltage of 1 kV or more, such as 1-5 kV.

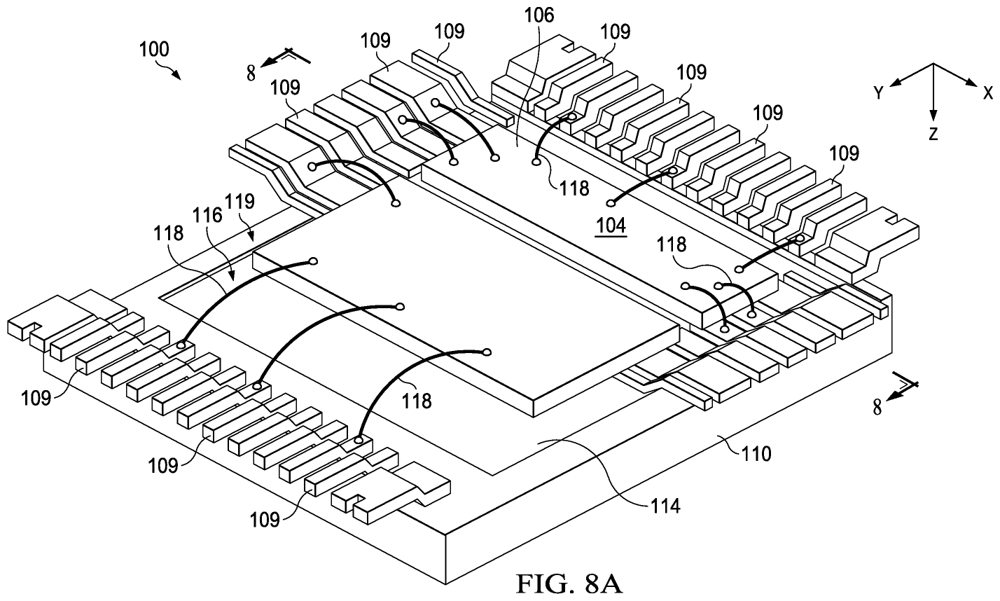

The packaged electronic device 100 includes electrical connections between conductive features (e.g., bond pads, not shown) of the semiconductor die 102 and respective ones of the leads 109. In one example, the electrical connections include bond wires 118 as shown in FIG. 1. The illustrated example includes more than one semiconductor die and associated bond wire connections between certain leads 109 and conductive features of the second semiconductor die, for example, as shown in FIG. 8A described further below. The packaged electronic device 100 also includes a package structure 120 that encloses the semiconductor die 104, the die attach pad 101 and the bond wires 118. In one example, the package structure 120 is or includes plastic molding compound. The package structure 120 exposes portions of the leads 109 for soldering to a PCB and exposes an upper portion of the second side 112 of the conductive plate 110 for heat dissipation.

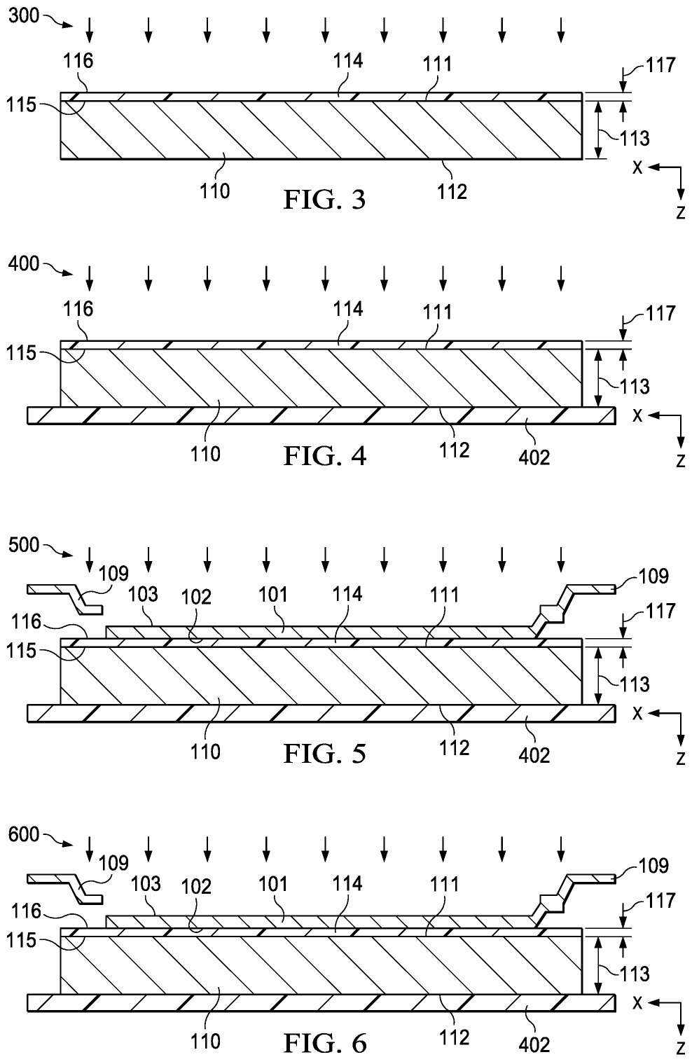

FIG. 2 shows a method 200 of manufacturing a packaged electronic device. The method 200 is illustrated and described herein in connection with fabrication of the example QFN type packaged electronic device 100 of FIG. 1. In other implementations, the method 200 can be performed in manufacturing different package types (e.g., QFP) of electronic devices. The method 200 begins at 202 with attaching a polymer layer to a side of a conductive (e.g., copper) plate. FIG. 3 shows the packaged electronic device 100 of FIG. 1 undergoing a deposition process 300 that deposits the polymer layer 114 on the conductive plate 110. The process 300 deposits the polymer layer by dispensing or other deposition processing with the first side 115 of the polymer layer 114 on the first side 111 of the conductive plate 110.

At 204 in FIG. 2, the second side 112 of the conductive plate 110 is mounted to an adhesive carrier tape for further processing. FIG. 4 shows the packaged electronic device 100 undergoing a pick and place process 400 that positions the conductive plate 110 on an adhesive carrier tape 402 and adheres the second side 112 of the conductive plate 110 to the adhesive carrier tape 402.

The method 200 continues at 206 and 208 with attaching the first side 102 of the die attach pad 101 to the second side 116 of the polymer layer 114. In one example, the first side 102 of the die attach pad 101 is attached to the second side 116 of the polymer layer 114 by placing the first side 102 of the die attach pad 101 on the second side 116 of the polymer layer 114 at 206. FIG. 5 shows a starting lead frame with the leads 109 inverted undergoing a pick and place process 500 that places the first side 102 of the die attach pad 101 on the second side 116 of the polymer layer 114. The method continues at 208 in this example with bonding the first side 102 of the die attach pad 101 to the second side 116 of the polymer layer 114 at a non-zero pressure while heating the polymer layer 114. FIG. 6 shows the packaged electronic device of FIG. 1 undergoing a heated pressure bonding process 600 that bonds the second side 116 of the polymer layer 114 to the first side 102 of the die attach pad 101. In one example, the bonding process at 208 is performed at a pressure of 20-30 kPa while heating the polymer layer 114 to a temperature of 130 to 160 degrees C. for 20 to 30 seconds.

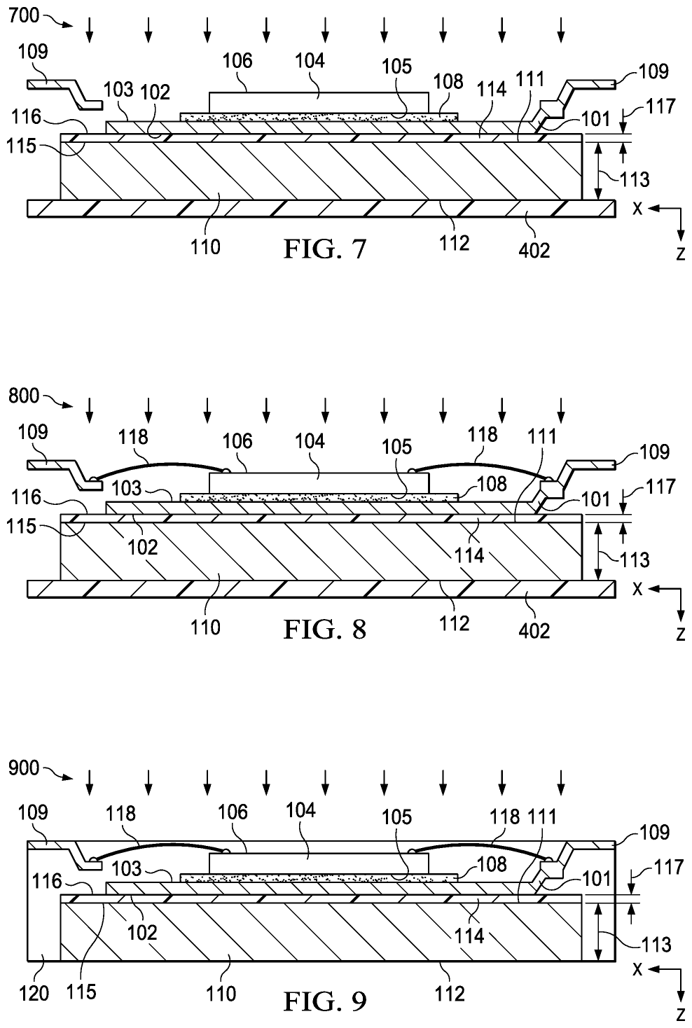

The method 200 continues at 210 with die attachment processing. FIG. 7 shows the packaged electronic device 100 undergoing a die attachment process 700 that attaches the semiconductor die 104 to the die attach pad 101. The process 700 in this example attaches the first side 105 of the semiconductor die 104 to the second side 103 of the die attach pad 101. In one example, the die attach processing at 210 also includes attaching a second or further semiconductor dies (e.g., FIG. 8A below) to other portions of the die attach pad 101. In the illustrated implementation, the first side 102 of the die attach pad 101 is attached to the second side 116 of the polymer layer 114 before the first side 105 of the semiconductor die 104 is attached to the second side 103 of the die attach pad 101. In another implementation (not shown), the die attachment of the semiconductor die 104 to the die attach pad 101 is performed before the polymer layer 114 is bonded on the die attach pad 101.

The method 200 continues at 212 with coupling a conductive feature of the semiconductor die 104 to a lead 109. FIG. 8 shows the packaged electronic device 100 undergoing a wire bonding process 800 that electrically couples conductive features of the semiconductor die 104 to one or more leads 109 of the starting lead frame using bond wires 118. FIG. 8A shows the packaged electronic device 100 following the wire bonding process 800 of FIG. 8, with bond wires 118 interconnecting various conductive features of two semiconductor dies, including the semiconductor die 114 with respective ones of the leads 109. The sectional view of FIG. 8 is taken along line 8-8 of the perspective view shown in FIG. 8A.

The method 200 continues at 214 with forming the package structure 120 that encloses the semiconductor die 104, the bond wires 118 and the die attach pad 101 and exposes a portion of the top or second side 112 of the conductive plate 110, as well as portions of the leads 109. FIG. 9 shows the packaged electronic device of FIG. 1 undergoing a molding process 900 to create the molded package structure 120. The method 200 continues at 216 with package separation (e.g., package sawing, not shown) to separate individual packaged electronic devices from one another. The manufacturing process yields the packaged electronic device 100 as shown above in the sectional view of FIG. 1.

The packaged electronic device 100 in this example provides a large and fully insulated top-side thermal pad for heat dissipation and easier thermal management during operation, with improved thermal performance compared with standard non-insulated QFN or QFP packages. The concepts of the disclosed examples can be used in other types and forms of packaged electronic devices. One example uses a 140 μm thick polymer layer 114, for example, a polymer-based, electrically isolated but thermally conductive material (e.g., thermal conductivity of 10 W per meter per degree K) to bond a thick copper plate 110 (e.g., 105 μm to 3 mm, such as 0.5 to 2 mm, for example 0.5 to 1 mm) and a standard copper lead frame for a QFN or QFP package. The exposed thermal pad area of this example increases more than 50% and the heat dissipation capability improves 40-60% depending on the copper plate thickness and thermal interface material used in a cooling system.

The disclosed examples can be used to provide a low cost and simple approach for mass production of a fully insulated packaged electronic devices, including QFN, QFP and other package types. The disclosed example maintains all advantages of the QFN or QFP packages, such as high pin density and small package parasitics, and provides an enhanced heat dissipation path from the semiconductor die 104 to the conductive plate 110 and any associated external heatsink or cold plate (not shown) attached to the conductive plate 110. In one example, the polymer layer 114 is a B-stage insulating film having a strong adhesion to thick copper plate 110 as well as to the die attach pad 101 of a standard copper lead frame by pressing at a controlled temperature. The polymer layer 114 facilitates electrical insulation with reliable bonding to the conductive plate 110 and die attach pad 101. The high thermal conductivity (e.g., 10 W per meter per degree K) of this material compared to that of other similar materials allows an effective heat transfer while providing an electrical insulation function. In another example, the polymer layer 114 is an epoxy material and has a thermal conductivity of 3 W per meter per degree K or more, such as 3-15 W per meter per degree K. In a further example, the polymer layer 114 is an epoxy material and has a thermal conductivity of 5 W per meter per degree K, such as 5-15 W per meter per degree K. In another example, the polymer layer 114 is an epoxy material and has a thermal conductivity of 12 W per meter per degree K or more, such as 12-15 W per meter per degree K. In these or other examples, the polymer layer 114 has a thickness of 120 to 200 μm or more, with a dielectric strength of 20-30 kV per mm. The described devices and methods, moreover, allow use of a thick conductive plate 110 to help distribute heat uniformly. The described solutions also have minimal change of assembly processing with addition of the polymer layer 114. Also, the described examples are of comparably lower cost than using a metallized ceramic substrate and an external machined copper plate for a similar package size, and the packaged electronic device 100 provides integrated isolation inside a power package for easy thermal management to meet safety standards. The described examples also maintain the original QFN or QFP pin configuration with enhanced thermal performance and isolation performance.

Modifications are possible in the described examples, and other implementations are possible, within the scope of the claims.

1. A packaged electronic device, comprising:
a die attach pad having a first side and an opposite second side;
a semiconductor die having a first side and an opposite second side, the first side of the semiconductor die mounted to the second side of the die attach pad;
a conductive plate having a first side and an opposite second side;
a polymer layer having a first side and an opposite second side, the first side of the polymer layer on the first side of the conductive plate, and the second side of the polymer layer on the first side of the die attach pad; and
a package structure, the package structure encloses the semiconductor die and the die attach pad, and the package structure exposes a portion of the second side of the conductive plate.

2. The packaged electronic device of claim 1, wherein the polymer layer has a dielectric strength of 10 kV/mm or more.

3. The packaged electronic device of claim 2, wherein the first side and the second side of the polymer layer are spaced apart from one another by a thickness of 140 μm or more.

4. The packaged electronic device of claim 3, wherein the polymer layer has a thermal conductivity of 5 W per meter per degree K or more.

5. The packaged electronic device of claim 2, wherein the polymer layer has a thermal conductivity of 5 W per meter per degree K or more.

6. The packaged electronic device of claim 2, wherein the first side and the second side of the conductive plate are spaced apart from one another by a plate thickness of 0.25 mm or more and 3.0 mm or less.

7. The packaged electronic device of claim 1, wherein the first side and the second side of the conductive plate are spaced apart from one another by a plate thickness of 0.25 mm or more and 3.0 mm or less.

8. The packaged electronic device of claim 7, wherein the plate thickness is 0.50 mm or more and 1.0 mm or less.

9. The packaged electronic device of claim 1, wherein the polymer layer has a breakdown voltage of 1 kV or more.

10. The packaged electronic device of claim 9, wherein the first side and the second side of the conductive plate are spaced apart from one another by a plate thickness of 0.25 mm or more and 3.0 mm or less.

11. A packaged electronic device, comprising:
a die attach pad enclosed by a package structure;
a semiconductor die mounted to a side of the die attach pad;
a conductive plate; and
a polymer layer having a first side on a side of the conductive plate, and a second side on the die attach pad.

12. The packaged electronic device of claim 11, wherein the polymer layer has a dielectric strength of 10 kV/mm or more.

13. The packaged electronic device of claim 12, wherein the polymer layer has a thickness of 140 μm or more.

14. The packaged electronic device of claim 11, wherein the polymer layer has a breakdown voltage of 1 kV or more.

15. The packaged electronic device of claim 14, wherein the conductive plate has a plate thickness of 0.25 mm or more and 3.0 mm or less.

16-20. (canceled)

21. A packaged electronic device, comprising:
a first side of a polymer layer attached to a first side of a conductive plate;
a first side of a die attach pad attached to a second side of the polymer layer;
a first side of a semiconductor die attached to a second side of the die attach pad;
a conductive feature of the semiconductor die coupled to a lead; and
a package structure that encloses the semiconductor die and the die attach pad and exposes a portion of a second side of the conductive plate.

22. The packaged electronic device of claim 21, wherein the polymer layer has a dielectric strength of 10 kV/mm or more.

23. The packaged electronic device of claim 22, wherein the first side and the second side of the polymer layer are spaced apart from one another by a thickness of 140 μm or more.

24. The packaged electronic device of claim 21, wherein the first side and the second side of the conductive plate are spaced apart from one another by a plate thickness of 0.25 mm or more and 3.0 mm or less.

25. The packaged electronic device of claim 21, wherein the polymer layer has a breakdown voltage of 1 kV or more.
